(19) United States
(12) Patent Application Publication
(10) Pub. No.: US 2007/0160099 A1
(43) Pub. Date: Jul. 12, 2007

(54) Multiple anneal induced disordering

(75) Inventors: John Haig Marsh, Glasgow (GB); Dan Andreyevitch Yanson, Glasgow (GB); Stewart Duncan McDougall, Hazelbank (GB)

Correspondence Address: DASPIN & AUMENT, LLP, 210 WEST 22ND STREET, SUITE 102, OAK BROOK, IL, 60523, US

(73) Assignee: INTENSE LIMITED, Glasgow (GB)

(21) Appl. No.: 10/596,327

(22) PCT Filed: Nov. 24, 2004
(86) PCT No.: PCT/GB04/04944

§ 371 Date: Nov. 17, 2006

(30) Foreign Application Priority Data
Dec. 10, 2003 (GB) 0328808.1

(51) Int. Cl. H01S 5/00

(52) U.S. Cl. 372/43.01; 372/45.01

(57) ABSTRACT

A quantum well intermixing (QWI) technique for modifying an energy bandgap during the formation of optical semiconductor devices differing bandgap shifts across a wafer, device or substrate surface. The method includes: pattering the surface of a semiconductor substrate with QWI-initiating material in first regions of the surface; conducting a first thermal processing cycle on the substrate to generate a first bandgap shifts in the first regions; pattering the surface of the substrate with QWI initiating material in second regions of the surface, distinct from said first regions; and conducting a second thermal processing cycle on the substrate to generate a second bandgap shift in the second regions, and to generate a cumulative bandgap shift in the first regions, the cumulative bandgap shift being the cumulative result of said first and second thermal processing cycles. Further steps can produce additonal cumulative bandgap shifts.

The present invention relates to quantum well intermixing (QWI) techniques suitable for modifying an energy bandgap during the formation of optical semiconductor devices. In particular, the invention relates to QWI techniques in which spatial control of the QWI process can be effected so as to achieve differing bandgap shifts across a wafer, device or substrate surface.

A vast body of research exists in the field of QWI. The QWI process consists in the selective disordering of the composition of the thin layers that form quantum wells, which results in a change of energy levels within each well causing the energy bandgap to shift. This allows one to alter the emission and absorption wavelengths of the intermixed material.

A variety of QWI techniques have been developed including: impurity-induced, impurity free (dielectric cap), implantation-induced and laser induced methods. QWI has been demonstrated in a range of material systems, including GaAs/AlGaAs and InP/AlInGaAs(P).

Much effort recorded in the prior art (prior art references are given in the Annex to this description, as referred to in square parentheses) has been directed to achieving a dual-bandgap process, where the emphasis is on obtaining a large differential shift between areas of reduced shift (nominally the as-grown bandgap) and intermixed areas. Various techniques have been proposed to enhance control over bandgap shifts, e.g. varying the material [1, 2], deposition conditions [3, 4], stoichiometry [5], size [6] and thickness [7-9] of the dielectric cap in impurity-free processes; ion irradiation dose [8, 10], laser exposure [11-14], surface coverage/resolution effects [15], and, most commonly, anneal temperature-e and duration in almost all of the above reports. Not all of these approaches, however, can be used to create multiple, i.e. greater than 2 bandgaps on a single wafer —by temperature adjustment alone one cannot obtain more than one shift.

Most generally, multiple bandgaps can be created using a core dual-bandgap process with one of the following approaches:
1. Repeated [10, 15-21] /variable dose [12-14] exposure-anneal combinations;
2. Choice of dielectric caps of different material [2-5] and interface effects [1, 22-24];
3. QWI barrier masks [7, 9, 25, 26] and caps of varying thickness [7, 8]; and
4. Spatial/resolution effects [6, 15]

Despite the abundance of QWI techniques, there is a scarcity of prior art where these techniques could be used in a controlled manner to define multiple bandgaps on a common substrate.

A first prior art approach is based upon use of repetitive cycles of ion-implantation/plasma exposure and rapid thermal anneal (RAT) at high-temperature to obtain required bandgap shifts [10, 15-21]. This approach has been used to tune the wavelength of quantum-well lasers [17, 27] and infrared photo detectors [20, 21]. Repetitive steps are employed to achieve larger cumulative shifts than those attainable with a single-anneal process [17-20, 28].

To achieve multiple bandgaps in selected areas using the above approach, one needs to pattern these areas and expose them to the implantation/anneal cycle, repeating the procedure for each shifted bandgap required, as suggested in [20]. Here, the underlying assumption is that subsequent intermixing cycles have no effect on the shifts in the areas processed at earlier stages as long as they are protected during subsequent exposures. This assumption is believed to be true for a range of ion-implantation techniques, as the shifts are best controlled by adjusting the irradiation dose [18, 20].

The situation is more complicated where anneal conditions are used to control the amount of intermixing. RAT affects areas of all bandgaps regardless of the order in which they were exposed, thus possibly shifting the bandgaps created previously even further. In the case of a combined implantation/anneal cycle, one can circumvent this problem by carrying out the multiple patterning and irradiation steps first, followed by a common anneal step at the end.

In report [29], multiple bandgaps were created using multiple anneals with a sacrificial ion implant layer, which was selectively removed in areas requiring no further shifting during subsequent anneals. In locations where the sacrificial layer was removed, QWI suppression was achieved such that subsequent anneals caused substantially no fier bandgap shift in those locations.

Such a solution is not possible, however, in QWI RAT-enabled processes where shifts are induced through impurity diffusion and/or by dielectric caps, in particular, in a sputtering-induced disordering (SID) process. The SID process involves sputter deposition of an impurity (such as sulphur, zinc, silicon, fluorine, copper, germanium, tin, selenium, etc onto the material surface) followed by a high-temperature anneal. Suppression of QWI (zero bandgap shift) is achieved by protecting the respective other areas of the substrate with a layer of PECVD-deposited silica.

Here, the high-temperature-induced creation and interdiffuision of defects during the anneal is the prime intermixing mechanism, which cannot always be fully suppressed by the removal of the defect/impurity source in subsequent anneal stages. In other words, while in irradiation/exposure-based processes the action of the intermixing agent (e.g. implantation dose or the defect-rich layer of [29]) can be limited to a particular intermixing step, in cap-based processes such action cannot always be suppressed in subsequent intermixing steps even by the removal of the QWI cap. Therefore, in the latter case, each subsequent RAT stage will uncontrollably affect the shifts obtained in all the previous steps.

In a second prior art technique, [15, 16] and many others, it is proposed to vary anneal duration to control QWI shift using dielectric caps. However, the only mention of a multiple anneal process being used in conjunction with a dielectric cap is found in [16]. InGaAs/InAlAs multiple-quantum well (MQW) structures were partially disordered by the deposition of a Si₃N₄ dielectric cap followed by repeated RTAs at 850 degrees C. for 1 to 5 seconds. The only reason given for doing so is to achieve a larger cumulative shift (43 nm) than that attainable with a single-anneal process. The paper [16] does not consider the creation of multiple bandgaps on a single substrate, nor the difficulty in overcoming unwanted further shifts in previously intermixed regions.

It is an object of the present invention to provide a QWI process that is capable of providing multiple bandgap shifts on a single device substrate using impurity diffusion and/or dielectric cap-based QWI.

According to one aspect, the present invention provides a method for producing multiple quantum well intermixed (QWI) regions having different bandgaps on a single substrate, comprising the steps of:
a) patterning the surface of the substrate with QWI-initiating material in first regions of the surface;
b) conducting a first thermal processing cycle on the substrate to generate a first bandgap shift in the first regions;
c) patterning the surface of the substrate with QWI-initiating material in second regions of the surface, distinct from said first regions; and
d) conducting a second thermal processing cycle on the substrate to generate a second bandgap shift in the second regions, and to generate a cumulative bandgap shift in the first regions, the cumulative bandgap shift being the cumulative result of said first and second thermal processing cycles.

According to another aspect, the present invention provides a method for determining required parameters for each of the thermal processing cycles of the method defined immediately above, comprising the steps of:
determining whether the process for generating cumulative bandgap shifts resulting from successive thermal processing cycles is symmetric or asymmetric;
if the process is symmetric, then determining the thermal process conditions required for each one of a plurality of cumulative bandgap shifts BG₁ to BG_{N} by successive use of at least one sample through a thermal process sequence A_{N} to A₁, where A₁ is the thermal process required to obtain BG_{N} from BG_{N-1}; A₂ is the thermal process required to obtain BG_{N-1} from BG_{N-2}; etc.; through to A_{N} being the thermal process required to obtain BG₁ from BG₀; and
if the process is asymmetric, then determining the thermal process conditions required for each one of the plurality of cumulative bandgap shifts BG₁ to BG_{N} by use of a plurality of samples through a partial or complete thermal process sequence in the order A₁ to A_{N} for each one of the bandgap shifts required.

Embodiments of the present invention will now be described by way of example and with reference to the accompanying drawings in which:

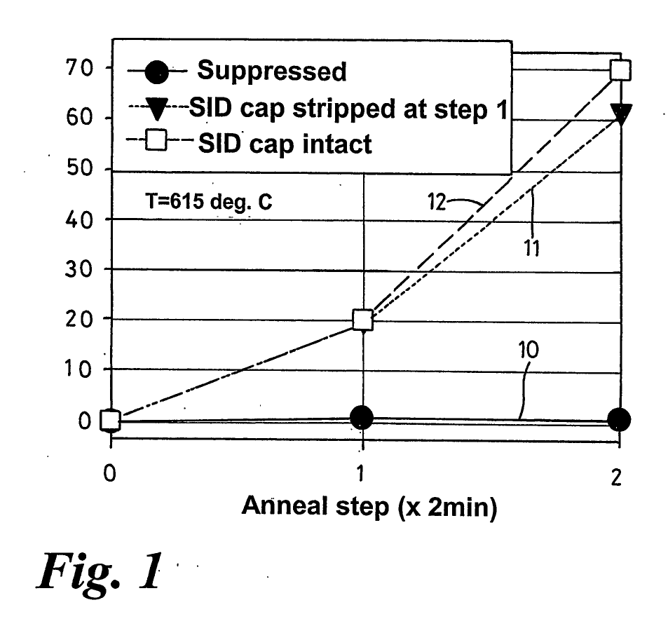

FIG. 1 is a graph illustrating the effects of a subsequent thermal anneal process on a substrate after a QWI-initiating layer has been stripped;

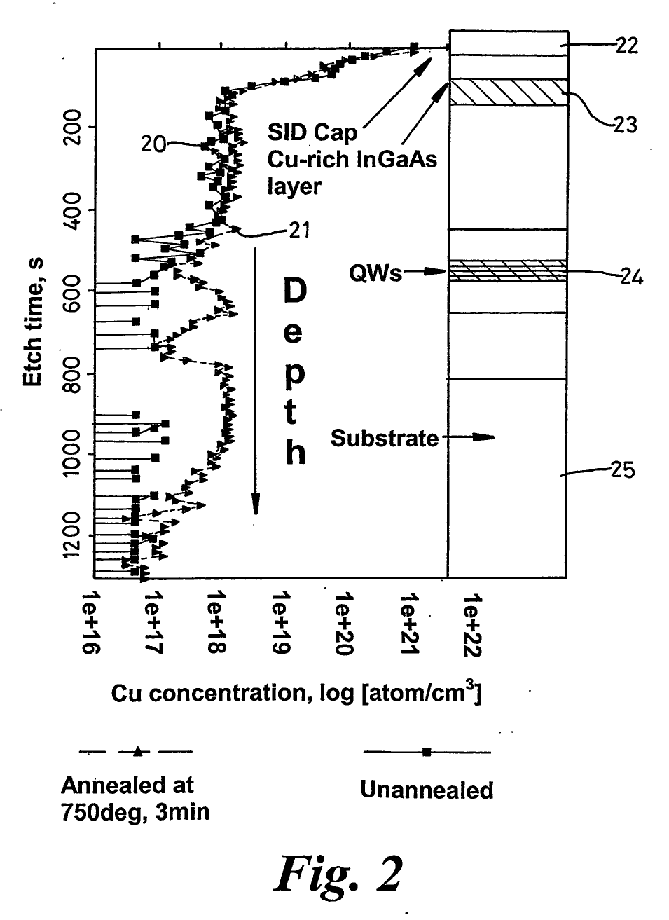

FIG. 2 is a graph illustrating impurity concentration as a function of depth through the substrate before and after QWI processing;

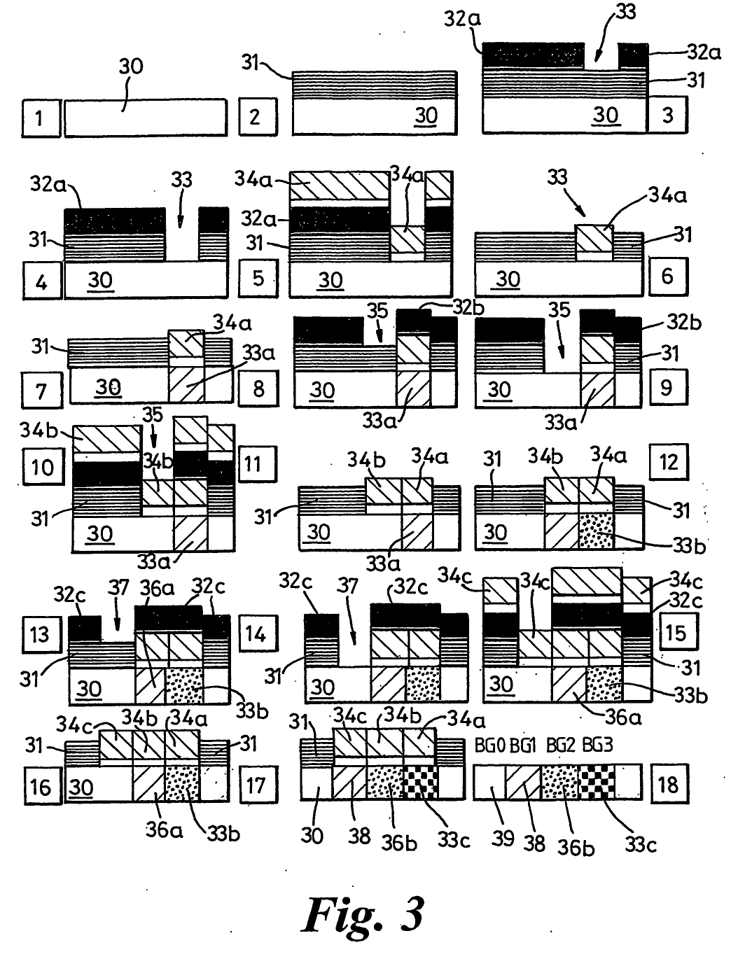

FIG. 3 is a schematic diagram of the device substrate during various stages of the QWI processing steps according to one embodiment of the present invention;

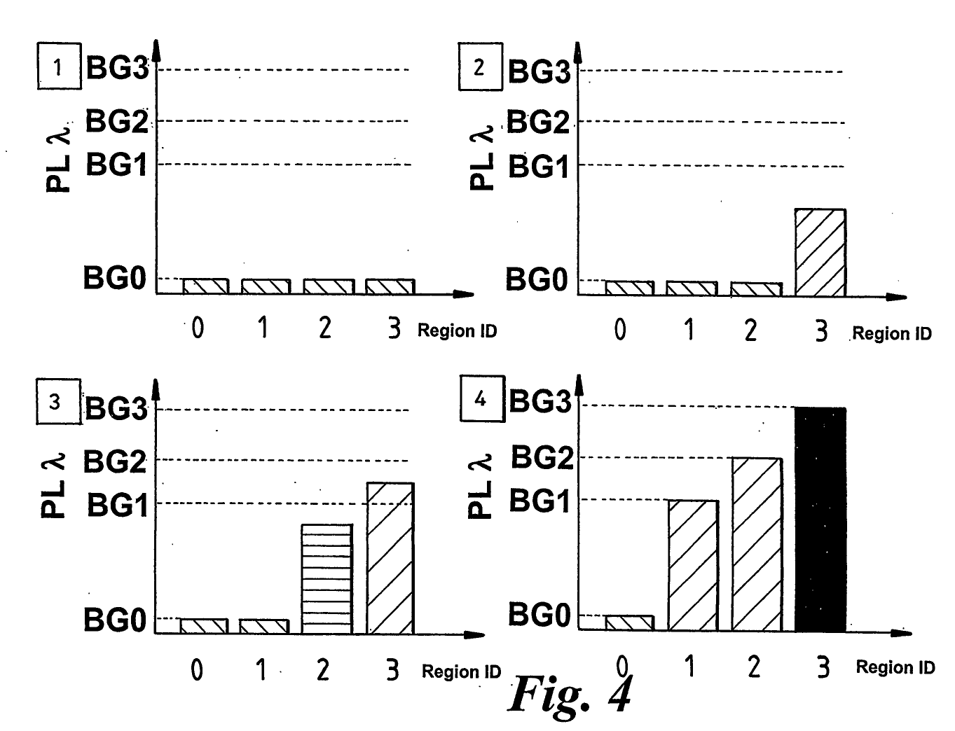

FIG. 4 shows schematically initial and subsequent bandgap shifts, represented by photoluminescence wavelength shift, effected in different regions of the substrate during the processing steps as applied to the structures of FIG. 3;

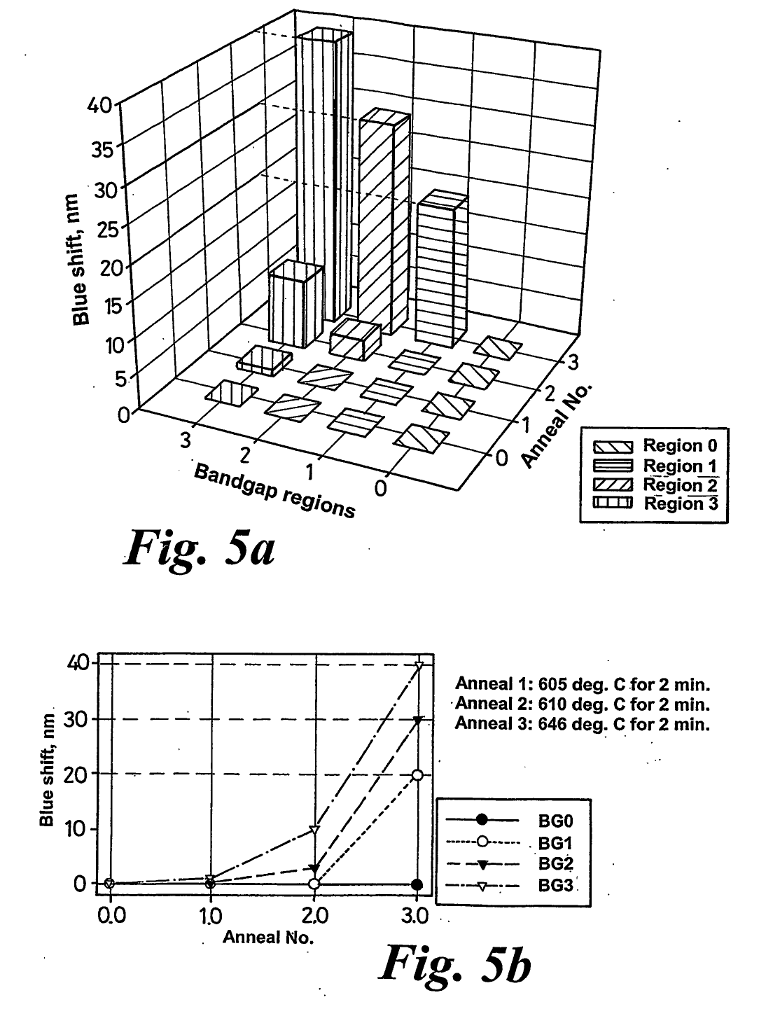

FIG. 5 shows experimentally measured initial and subsequent bandgap shifts, represented by photoluminescence wavelength shift, effected in different regions of the substrate during the processing steps as applied to the structures of FIG. 3, in 3D graph form (FIG. 5a) and in 2D graph form (FIG. 5b);

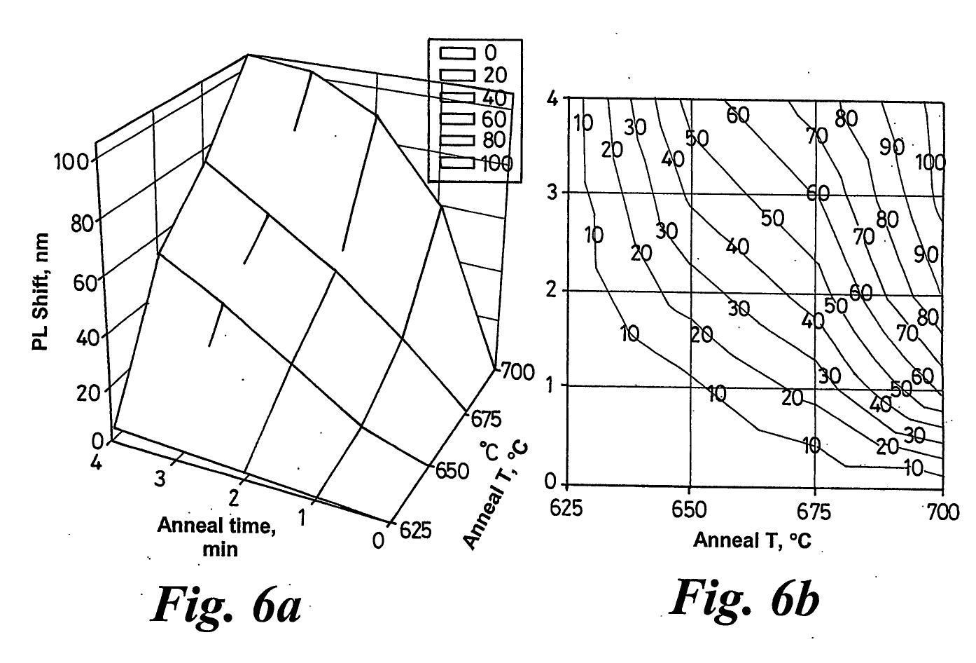

FIG. 6 shows bandgap shifts, represented by photoluminescence wavelength shift, as a function of anneal time and anneal temperature in 3D graph form (FIG. 6a) and in 2D graph form (FIG. 6b); and

FIG. 7 shows a procedural flow chart for generating the required anneal conditions for a desired set of bandgaps.

The process of the present invention allows multiple bandgaps to be defined in a controlled manner, in several intermixing steps, on the same wafer or substrate. The process is compatible, inter alia, with Al-quaternary InP material on a semi-insulating (SI) InP substrate, and thus can be used to fabricate high-frequency optoelectronic devices. This enables a plethora of component integration possibilities whereby active and passive components, each bandgap-tuned as required, can be fabricated on a common substrate as part of a photonic integrated circuit and/or a single integrated device. Examples include semiconductor optical amplifier (SOA)-preamplified modulators, photo detectors and switches, extended-cavity lasers, wavelength-detuned laser arrays, demultiplexors, etc.

It has been established that in many QWI RAT-enabled processes where shifts are induced through impurity diffusion and/or by QWI-initiating dielectric caps, after initial annealing, the removal of the QWI-imitiating dielectric cap after one thermal processing step has little effect on the shifts obtained in subsequent thermal processing steps. In other words, following the first QWI step, the shifts obtained with and without the QWI-initiating cap on are almost identical. This effect is clearly illustrated in FIG. 1.

FIG. 1 shows the photoluminescence wavelength shift resulting from various QWI processes, being a direct measurement of the bandgap shift. In the reference sample indicated by line 10, no QWI-initiating cap is applied to the substrate. In the first sample, indicated by dotted line 11, a QWI-initiating cap is applied for the anneal process step 1, and stripped for the subsequent anneal process step 2. By way of contrast, in the second sample, indicated by dashed line 12, a QWI-initiating cap is applied for the anneal process step 1 and maintained for the subsequent anneal process step 2. It can readily be seen by comparison of lines 11 and 12 that the stripping of the QWI-initiating cap after the first anneal has only a marginal effect on the shift induced by the second anneal. The anneal process 1 and anneal process 2 each correspond to an isothermal anneal for 2 minutes at 615° C. on a multiple quantum well structure in InP/InAlGaAs material.

Further processing, such as removal of the top semiconductor layers in contact with the QWI-initiating layer, will not normally enable the total suppression of farther bandgap shifting with subsequent thermal processing. FIG. 2 shows the concentration of the QWI-initiating impurity (in this example, copper) as a function of depth into the substrate (indicated by etch time in seconds) for both unannealed samples (profile 20) and for samples annealed at 750 degrees C. for 3 minutes (profile 21), as measured by SIMS. The QWI-initiating cap layer 22, the impurity-rich InGaAs layer 23, quantum well layers 24 and mechanically supporting substrate 25 are shown to the right of the graph. It is noted that a number of possible impurity materials may be used for QWI initiation. These include sulphur, zinc, silicon, fluorine, copper, germanium, tin and selenium.

For the avoidance of doubt, it is noted that throughout the present specification and particularly including the claims, for brevity and clarity the expression ‘substrate’ is used in a general sense to include the mechanically supporting and ‘original’ substrate 25 and all further material layers in existence above that original substrate at the time of a subsequent process step. In other words, the expression ‘substrate’ is intended to cover the totality of previously processed material and layers to which a process or further process (e.g. layer deposition or thermal treatment) is to be applied. The original ‘raw material’ substrate will be referred to as the mechanically supporting substrate, although it will be understood that this too may change its physical and chemical characteristics during processing.

As shown by the concentration distribution of the QWI-enabling impurity measured by the SIMS analysis before and after annealing with the QWI-initiating cap on, the impurity has penetrated the material very deeply, far beyond the active region containing the quantum wells. The high concentration of the impurity that has diffused into the material after the initial anneal step can cause further intermixing at subsequent anneals even if the impurity source located in the top layers is removed. Therefore, suppression of further bandgap shifting by removal of the QWI-initiating layer 22 (or layers 23 below) is not likely to be successful in many processes.

The multiple anneal process of the present invention is illustrated for the multi-bandgap intermixing of InP/InGaAs material on a SI InP substrate using the dual-bandgap SID process described above.

FIG. 3 illustrates the process steps carried out on a device substrate for intermixing InP/AlInGaAs material to obtain four different bandgaps (including the as-grown one). The topmost semiconductor layer 30 of an as-grown epi wafer structure is represented in FIG. 3-1. The target bandgaps are referred to herein, in order of increasing shift, as BG₀, BG₁, BG₂ and BG₃. BG₀ corresponds to the as-grown (non-intermixed) bandgap.

In step 2 (FIG. 3-2), the substrate 30 is covered with a blanket layer of PECVD silica 31.

In step 3 (FIG. 3-3), a photoresist layer 32a is deposited onto the wafer and is photolithographically patterned to expose regions 33 targeted to have the largest eventual bandgap BG₃.

In step 4 (FIG. 3-4), the PECVD silica 31 in the exposed windows 33 is removed by wet-etching using an HF-based etchant.

In step 5 (FIG. 3-5), a QWI-initiating cap 34a consisting of a layer of an impurity and then a layer of silica is sputtered across the wafer.

In step 6 (FIG. 3-6), the QWI-initiating cap 34a is lifted off in all areas where it overlies the photoresist layer 32a using a conventional photoresist lift off process to leave the QWI-initiating cap 34a in the BG₃ region 33 and to leave the QWI-inhibiting PECVD layer 31 in all regions where. QWI is to be suppressed.

In step 7 (FIG. 3-7), the wafer is intermixed by high-temperature rapid thermal anneal, to generate a bandgap shifted region 33a (eventually targeted to have the largest bandgap shift BG₃).

In step 8 (FIG. 3-8), a photoresist layer 32b is deposited onto the wafer 30 and is photolithographically patterned to expose regions 35 targeted to have the next largest bandgap BG₂.

In step 9 (FIG. 3-9), the PECVD silica 31 in the exposed windows 35 is removed by wet-etching using an HF-based etchant.

In step 10 (FIG. 3-10), a QWI-initiating cap 34b consisting of a layer of an impurity and a layer of silica is sputtered across the wafer.

In step 11 (FIG. 3-11), the QWI-initiating cap 34b is lifted off in all areas where it overlies the photoresist layer 32b using a conventional photoresist lift off process to leave the QWI-initiating cap 34b in the BG₂ region 35 and to leave the QWI-inhibiting PECVD layer 31 in all regions where QWI is to be suppressed.

In step 12 (FIG. 3-12), the wafer is intermixed by high-temperature rapid thermal anneal, to generate a bandgap shifted region 36a (eventually targeted to have the next largest bandgap shift BG₂) and to further modify the bandgap of the BG₃ region, 33b.

In step 13 (FIG. 3-13), a photoresist layer 32c is deposited onto the wafer 30 and is photolithographically patterned to expose regions 37 targeted to have the smallest shifted bandgap BG₁.

In step 14 (FIG. 3-14), the PECVD silica 31 in the exposed windows 37 is removed by wet-etching using an HF-based etchant.

In step 15 (FIG. 3-15), a QWI-initiating cap 34c consisting of a layer of an impurity and a layer of silica is sputtered across the wafer.

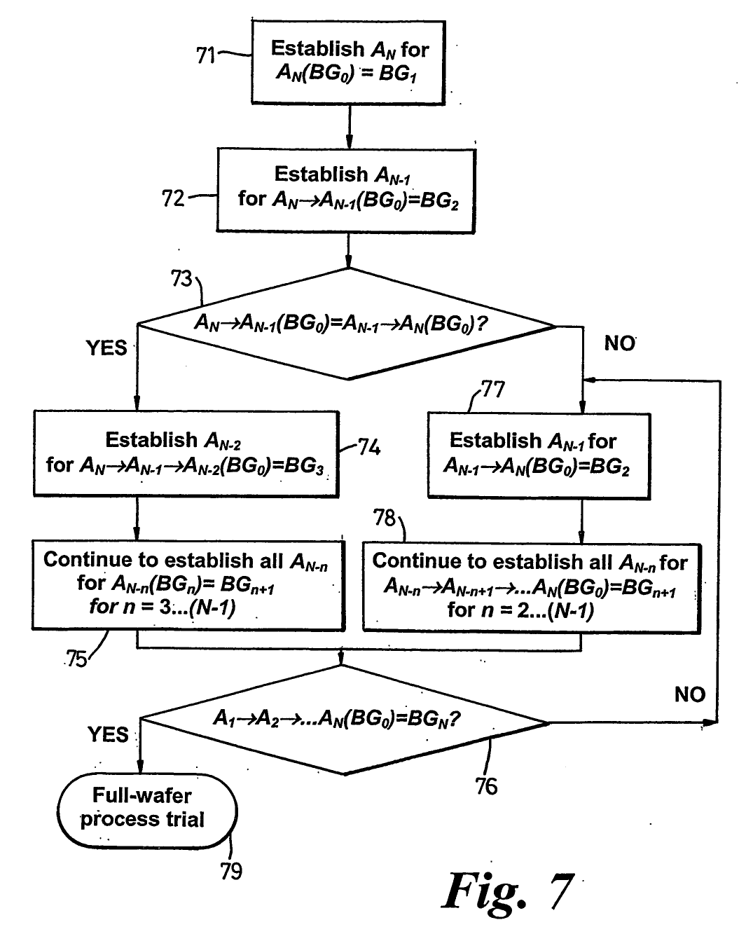

In step 16 (FIG. 3-16), the QWI-initiating cap 34c is lifted off in all areas where it overlies the photoresist layer 32c using a conventional photoresist lift off process to leave the QWI-initiating cap 34c in the BG₁ region 37 and to leave the QWI-inhibiting PECVD layer 31 in all regions where QWI is to be suppressed.

In step 17 (FIG. 3-17), the wafer is intermixed by high-temperature rapid thermal anneal, to generate a bandgap shifted region 38 (with bandgap shift BG1); to firmer modify the bandgap of the region 36b to its final bandgap shift BG₂, and to further modify the bandgap of the region 33c to its final bandgap shift BG₃.

In step 18 (FIG. 3-18), the QWI-initiating cap layers 34a, 34b and 34c, as well as any QWI-inhibiting cap layer 31 are removed by wet-etching using an HF-based etchant. The result is the regions 39 having bandgap BG₀ (unshifted); regions 38 having bandgap shift BG₁; regions 36b having bandgap shift BG₂; and regions 33c having bandgap shift BG₃.

It will be understood that the process described above can be extended in principle to any number of different bandgaps.

It is important to note that the target bandgaps BG₀ to BG₃ are not fully defined until after the final anneal step (step 17 above). The evolution of the amount of intermixing in Regions 0 to 3 designated for bandgaps BG₀ to BG₃ with each anneal step is illustrated in FIG. 4. The as-grown case of zero shifts in all regions is shown in FIG. 4-1. With each anneal step represented in FIGS. 4-2, 4-3 and 4-4, the shifts are accumulated in the regions subjected to multiple anneals with the QWI-initiating cap on and only meet the target shifts BG₀ to BG₃ on completion of the final (in this case, third) anneal step of FIG. 4-4.

In a general aspect, it will be recognised that the above process effectively comprises patterning the substrate surface with QWI-initiating material in first regions of the surface, conducting a first thermal process on the substrate to generate a first bandgap shift in the first regions, patterning the surface of the substrate with QWI-initiating material in second regions of the surface, distinct from said first regions, and conducting a second thermal process on the substrate to generate a second bandgap shift in the second regions, and to generate a cumulative bandgap shift in the first regions, the cumulative bandgap shift being the cumulative result of said first and second thermal processing cycles.

This can be followed by further steps of patterning the surface of the substrate with QWI-initiating material in third regions of the surface, distinct from said first regions and said second regions, and conducting a third thermal processing cycle on the substrate to: (i) generate a third bandgap shift in the third regions, (ii) generate a cumulative bandgap shift in the second regions, the cumulative bandgap shift in the second regions being the cumulative result of the second and third thermal processing cycles; and (iii) generate a further cumulative bandgap shift in the first regions, the cumulative bandgap shift in the first regions being the cumulative result of the first, second and third thermal processing cycles.

Thereafter, further steps can be added for still more bandgaps, patterning the surface of the substrate with QWI-initiating material in other regions of the surface, distinct from all regions of the surface previously covered with QWI-initiating material, and conducting a subsequent thermal processing cycle to generate a bandgap shift in the other regions, and to generate cumulative bandgap shifts in all regions previously covered with QWI-initiating material prior to the most recent patterning step, the cumulative bandgap shifts each being the cumulative result of all thermal processing cycles to which the respective region has been exposed since being first covered with the QWI-initiating material.

The results of an experimental demonstration of the above process are given in FIG. 5, where target photoluminescence shifts of 20, 30 and 40 mn are obtained in InP/AlInGaAs MQW material using the core SID process after a series of three anneals each of identical duration (2 min) but at different temperatures (605, 610 and 646° C.). The intermediate shifts at each anneal stage are also shown.

As pointed out earlier, QWI shifts can be controlled by a combination of anneal temperature and time. This is further demonstrated using the SID process, with the results presented in FIG. 6 as a 3D surface in the anneal temperature-time-bandgap shift space (FIG. 6a) and as a contour plot (FIG. 6b). The data are obtained by sequential isothermal anneals of one sample and measurement of photoluminescence shifts after each step, with the procedure repeated with different samples for a range of temperatures.

The shifts obtained by a series of individual anneals and a single long anneal of the same total duration were found to be almost identical.

The process described above is capable of achieving the same range of bandgap shifts as are obtained by a conventional single anneal process that obtains just two bandgaps (i.e. the as-grown bandgap and the QWI bandgap). Furthermore, a large number of sequentially increasing bandgaps with arbitrary spacing are achievable. This is evident from the continuity of the data of FIGS. 6a and 6b, which confirm that a series of anneals of the same duration and temperature can be replaced with a single anneal, of a different duration and temperature, that produces an identical shift (i.e., any point that lies on the same iso-shift contour line of FIG. 6b).

The same is true for a series of non-isothermal anneals of varying durations, provided that the total shift is less than the fall shift obtainable with the dual-bandgap process (i.e., the saturation of bandgap shift as a function of anneal temperature/time). Note that this assumption is not applicable to techniques that utilise multiple anneals to achieve shifts that cannot be obtained with a single-stage anneal, as in [16], which would result in singularities in plots similar to those of FIG. 6. In that case, while the general concept described herein may still be used, only limited combinations of bandgaps may be achieved.

To define N shifted bandgaps, BG₁. . . BG_{N}, with BG₀ being the zero-shifted one, the multiple anneal process requires N anneal steps A₁. . . A_{N}, with each step having unique anneal conditions (temperature and duration). The least-shifted bandgap, BG₁, is obtained by the final anneal step A_{N}, which we express as A_{N}(BG₀) =BG₁. The largest bandgap, BG_{N}, conversely, is the result of all the anneals A₁. . . A_{N}, which can be written as A₁→A₂→ . . . →A_{N}(BG₀)=BG_{N}.

For the simplest case of N=2, having established A₂ for A₂(BG₀)=BG₁, one can always find anneal conditions A₁such that A₁→A₂(BG₀) =BG₂. This follows from the assumption that the sequence A₁→A₂ can be replaced with a single anneal under different conditions producing an equivalent shift, as stated above. Therefore, in a general case of N bandgaps, to define the nth bandgap, one can represent the required shift BGₙ as the superposition of anneal A_{N-n+1} and the combination of all the subsequent anneals A_{N-n+2}→ . . . →A_{N}, all of which, again, can be replaced with a single-stage anneal. This case is thus reduced to that of N=2, where the feasibility of the process has been proven.

In order to realise the multiple anneal process with specific bandgap targets in mind, a set of anneal conditions (anneal temperature and time) must be established for each anneal stage. The development of conditions for the multiple anneal process can be quite time and labour-consuming. Thus a strategic approach is proposed, designed to obtain the required set of conditions with minimum effort.

Preferably, the multiple anneal process development is carried out using small test pieces, which are cleaved from a larger piece of unannealed material having a blanket QWI-initiating cap. This way, no multiple photolithography/sputtering steps are required. The method is illustrated in the block diagram of FIG. 7.

In step 71, anneal conditions for step A_{N} are established in order to obtain the least-shifted bandgap BG₁.

In step 72, the resulting samples intermixed to BG, are used to establish the conditions for step A_{N}. Note the reverse anneal order: A_{N}→A_{N-}as opposed to A_{N}→A_{N}.

In step 73, the anneals are then performed in the correct order: A_{N-1}→1-A_{N} using as-grown samples BG₀. The two shifts obtained by annealing in reverse and normal order are then compared and process symmetry is ascertained. The process is symmetric, i.e. commutative, if the order in which anneals are performed has no effect on the aggregate shift. This largely depends on the combination of the material and the core dual-bandgap process being used. The process is described as asymmetric, i.e. non-commutative, if the order in which anneals are performed affects the total shift.

In step 74, if the process is symmetric, the anneal conditions for the next step A_{N-2} can be established using the BG₂ bandgap samples obtained at the previous stage. This greatly simplifies the tuning procedure to find the anneal conditions required, as several BG₂ bandgap samples can be prepared simultaneously and then used to search for optimum anneal parameters A_{N-2} as in the simplest single-anneal case.

In step 75, if further bandgaps are required, the procedure of step 74 is performed repetitively for each subsequent bandgap.

In step 76, the conditions for all steps are verified by performing all anneals in the correct order: A₁→A₂ → . . . →A_{N}(BG₀)=BG_{N}.

In step 77, if the conditions for the tests in steps 73 and/or 76 are not satisfied, then the process is non-symmetric, and a rigorous tuning procedure must be adopted. The procedure then only permits use of virgin BG₀ samples for the development of each step. Specifically for bandgap BG₂, each iteration of parameters A_{N-1}, must be followed by the previously established anneal A_{N}. Only then can the PL be measured and A_{N-1} adjusted.

In step 78, if further bandgaps are required, the procedure of step 77 is performed repetitively for each subsequent bandgap. In a general case, for bandgap BGₙ₊₁, each iteration of corresponding anneal parameters A_{N-n}(BG₀) must be followed by all of the previously established anneals A_{N-m}→ . . . . →A_{N} (where m=(n−l). . . 1) before any adjustments to A_{N-n} can be made.

In step 76, if the above procedure is performed correctly, then the verification condition A₁→A₂→ . . . →A_{N}(BG₀)=BG_{N} should be satisfied.

In step 79, the complete multiple anneal process should be verified on a full wafer using the flow of FIG. 3 and the established anneal parameters A₁. . . A_{N}.

It has been established that in the majority of multiple anneal processes, the process is found to be non-symmetric, thus necessitating adherence to the rigorous procedure of steps 77 and 78.

It is preferred that the duration of all anneal steps A₁. . . A_{N} should be equal, while any QWI shift adjustments are made by varying the temperature only. This way, the risk of the process performing differently on a fall wafer compared to small test pieces is minimized, as for short anneal times the intermixing rate may be affected by the sample size.

Although the exemplary embodiments above have been described in connection with an impurity-based QWI-initiating layer, other types of QWI-initiating materials and techniques may be used to initiate, accelerate or promote the intermixing process. These include impurity-free dielectric caps, sputtered materials (e.g. silica), plasma/sputter damage and some of the techniques outlined in the review of the prior art above.

Although the exemplary embodiments above have been described in connection with a QWI-inhibiting layer of PECVD silica layer, other types of QWI-inhibiting materials may be used to inhibit, suppress or otherwise retard the intermixing process. These include spin-on glass, sputtered silica etc.

Embodiments of the invention offer a number of advantages. No QWI-initiating later stripping is required after each intermixing step. They can all be stripped after the final step. No QWI-inhibiting layer deposition step is required after each intermixing step. The initially deposited layer can be relied upon. It is possible to create a large number of bandgap shifts of arbitrary magnitude and these can readily be altered. The process can be made compatible with a wide range of different materials systems including Al-quatemary InP material systems on a semi-insulating InP substrate.

Other embodiments are intentionally within the scope of the accompanying claims.
Annex 1: References
[1] Y. Hee Taek, et al, “Effect of dielectric-semiconductor capping layer combination on the dielectric cap quantum well disordering of InGaAs/InGaAsP quantum well structure”, Technical Digest. CLEO/Pacific Rim '99. Pacific Rim Conference on Lasers and Electro Optics Cat. No. 99TH8464., vol. 3, pp. 3, 1999.
[2] Y. Jae Su et al, “Effects of In/sub 0.53/Ga/sub 0.47/As cap layer and stoichiometry of dielectric capping layers on impurity-free vacancy disordering of In/sub 0.53/Ga/sub 0.47/As/InP multiquantum well structures”, J. Appl. Phys, vol. 88, pp. 5720-3, 2000.
[3] W. J. Choi, et al, “Control of the intermixing of InGaAs/InGaAsP quantum well in impurity free vacancy disordering by changing NH/sub 3/flow rate during the growth of SiN/sub x/capping layer”, Infrared Applications of Semiconductors III. Symposium Materials Research Society Symposium Proceedings, vol. 607, pp. 515-18, 2000.
[4] Y. Jae Su, et al, “Influence of dielectric deposition parameters on the In/sub 0.2/Ga/sub 0.8/As/GaAs quantum well intermixing by impurity-free vacancy disordering”, J Appl. Phys, vol. 92, pp. 1386-90, 2002.
[5] Y. Jae Su, et al, “Dependence of band gap energy shift of In/sub 0.2/Ga/sub 0.8/As/GaAs multiple quantum well structures by impurity-free vacancy disordering on stoichiometry of SiO/sub x/and SiN/sub x/capping layers”, J AppL. Phys, vol. 91, pp. 4256-60, 2002.
[6] W. J. Choi, et al, “Multiple wavelength lasers defined by stripe-width using one step impurity free quantum well intermixing technique”, Proceedings of the SPIE International Soc. for Optical Engineering, vol. 3628, pp. 267-74, 1999.
[7] H. S. Lim, et al, “A novel fabrication technique for multiple-wavelength photonic-integrated devices in InGaAs-InGaAsP laser heterostructes”, IEEE Photonics Technology Letters. May, vol. 14, pp. 594-6, 2002.
[8] X. F. Liu, et al, “Control of multiple bandgap shifts in InGaAs-AlInGaAs multiple-quantum-well material using different thicknesses of PECVD SiO/sub 2/protection layers”, IEEE Photonics Technology Letters, vol. 12, pp. 1141-3, 2000.
[9] S. L. Ng, et al, “A low-cost solution in generating multiple-bandgaps for 1.55 mu m optical fibre conmunications”, Leos, pp. 626-7, 2001.
[10] P. G. Piva, et al, “Enhanced compositional disordering of quantum wells in GaAs/AlGaAs and InGaAs/GaAs using focused Ga/sup +/ion beams”, AppL Phys. Letters, vol. 65, pp. 621-3, 1994.
[11] J. J. Dubowsli, et al, “Monolithic multiple wavelength ridge waveguide laser array fabricated by Nd:YAG laser-induced quantum well intermixing”, J. Vacuum Science & Technology A Vacuum, Surfaces, and Films. July, vol. 20, pp. 1426-9, 2002.
[12] T. K Ong, et al, “Fabrication of multiple-wavelength lasers in InGaAs-InGaAsP structures using direct laser writing”, IEEE Photonics Technology Letters. Nov., vol. 13, pp. 1161-3, 2001.
[13] T. K. Ong, et al, “Wavelength tuning in InGaAs/InGaAsP quantum well lasers using pulsed-photoabsorption-induced disordering”, Appl. Phys. Letters, vol. 78, pp. 2637-9, 2001.
[14] T. K. Sudoh, et al, “Wavelength trimming of distributed-feedback lasers by photo-absorption-induced disordering”, Conference Proceedings. LEOS '96 9th Annual Meeting. IEEE Lasers and Electro Optics Soc, pp. 419-20, 1996.
[15] B. S. Ooi, et al, “Selective Quantum-Well Intermixing in GaAs-AlGaAs Structures Using Impurity-Free Vacancy Diffusion”, IEEE J. Q. Elect., vol. 33, pp. 1784-1793, 1997.
[16] T. Miyazawa, et al, “Compositional disordering of In/sub 0.53/Ga/sub 0.47/As/In/sub 0.52/Al/sub 0.48/As multiquantum well structures by repetitive rapid thermal annealing”, Japanese J. of,Appl Phys, Part, vol. 28, pp. L730-3, 1989.
[17] B. S. Ooi, et al, “Plasma-based integration process for photonic integrated circuits”, CLEO '95. Summaries of Papers Presented at the Conference on Lasers and Electro Optics IEEE Cat. No. 95CH35800., vol. 224, pp. 224, 1995.
[18] P. G. Piva, et al, “Bandgap tuning of semiconductor quantum well structures using ion implantation”, Superlattices and Microstructures, vol. 15, pp. 385-9, 1994.
[19] P. J. Poole, et al, “The enhancement of quantum well intermixing through repeated ion implantation”, Semiconductor Science and Technology. Nov., vol. 9, pp. 2134-7, 1994.
[20] L. Fu, et al, “Tuning of detection wavelength of quantum-well infrared photodetectors by quantum-well intermixing”, Infrared Physics & Technology, vol. 42, pp. 171-175, 2001.
[21] A. G. Steele, et al, “Postgrowth tuning of quantum-well infrared detectors by rapid thermal annealing”, in Selected Papers on Quantum Well Intermixing for Photonics, SPIE Milestone Series MS145, E. H. Li, Ed., 1998, pp. 497-499.
[22] K. Hyun Soo, et al, “Quantum well intermixing of In/sub 1-x/Ga/sub x/As/InP and In/sub 1-x/Ga/sub x/As/In/sub 1-x/Ga/sub x/As/sub 1-y/P/sub y/multiple-quantum-well structures by using the impurity-free vacancy diffusion technique”, Semiconductor Science and Technology. Oct., vol. 15, pp. 1005-9, 2000.
[23] H. T. Yi, et al, “Effect of dielectric and semiconductor cap layer combinations in impurity free vacancy disordering of an InGaAs/InGaAsP single quantum well structure”, Sae Mulli. Sept., vol. 41, pp. 193-8, 2000.
[24] H. T. Yi, et al, “Dependence of quantum well disordering of IGaAs/InGaAsP quantum well structures on the various combinations of semiconductor-dielectric capping layers”, J. Materials Science Letters, vol. 19, pp. 835-6, 2000.
[25] S. L. Ng, et al, “Polarisation-dependent performance of multiple wavelength electro-absorption intensity modulator arrays on a single InGaAs/InGaAsP chip”, Leos, pp. 40-1, 2001.
[26] V. Aimez, et al, “High precision metal masking for multiple wavelength laser diode fabrication using single step ion implantation induced quantum well intermixing”, Proceedings of the SPIE The International Society for Optical Engineering, vol. 4087, pp. 607-15, 2000.
[27] M. Paquette, et al, “Blueshifting of InGaAsP/InP laser diodes by low-energy ion implantation”,. Appl Phys Letters, vol. 71, pp. 3749-51, 1997.
[28] H. H. Tan, et al, “Improved intermixing in GaAs/AlGaAs quantum well structures through repeated implant-anneal sequence”, presented at Conference on Optoelectronic and Microelectronic Materials and Devices Proceedings, Perth, December 14-16, 1998.
[29] L. A. Coldren, “ECE Technical Report 03-02: 2002 Reprints of Professor Larry A. Coldren and Collaborators”, Department of Electrical & Computer Engineering, University of California, Santa Barbara 2002.
[30] L. A. Coldren, “Publication List, section 1B “Quantiun-Well-Intermixing for Photonic ICs”, http://www.ece.ucsb.edu/Faculty/Coldren/reprints/2002Reprint/2002Listof Pubs.pdf ed: Department of Electrical & Computer Engineering, University of California, Santa Barbara, 2003.

1. A method for producing multiple quantum well intermixed (QWI) regions having different bandgaps on a single substrate, comprising the steps of:
a) patterning the surface of the substrate with QWI-initiating material in first regions of the surface;
b) conducting a first thermal processing cycle on the substrate to generate a first bandgap shift in the first regions;
c) patterning the surface of the substrate with QWI-initiating material in second regions of the surface, distinct from said first regions; and
d) conducting a second thermal processing cycle on the substrate to generate a second bandgap shift in the second regions, and to generate a cumulative bandgap shift in the first regions, the cumulative bandgap shift being the cumulative result of said first and second thermal processing cycles.

2. The method of claim 1 further including the steps of:
e) patterning the surface of the substrate with QWI-initiating material in third regions of the surface, distinct from said first regions and said second regions; and
conducting a third thermal processing cycle on the substrate to: (i) generate a third bandgap shift in the third regions, (ii) generate a cumulative bandgap shift in the second regions, the cumulative bandgap shift in the second regions being the cumulative result of the second and third thermal processing cycles; and (iii) generate a further cumulative bandgap shift in the first regions, the cumulative bandgap shift in the first regions being the cumulative result of the first, second and third thermal processing cycles.

3. The method of claim 2 further including the steps of:
g) patterning the surface of the substrate with QWI-initiating material in other regions of the surface, distinct from all regions of the surface previously covered with QWI-initiating material;
h) conducting a subsequent thermal processing cycle to generate a bandgap shift in the other regions, and to generate cumulative bandgap shifts in all regions previously covered with QWI-initiating material prior to the most recent patterning step, the cumulative bandgap shifts each being the cumulative result of all thermal processing cycles to which the respective region has been exposed since being first covered with the QWI-initiating material.

4. The method of claim 1 further including the step of covering adjacent regions of the substrate not covered with QWI-initiating material with QWI-inhibiting material.

5. The method of claim 1 in which at least one of the thermal processing cycles comprises a rapid thermal anneal cycle.

6. The method of claim 5 in which all of the thermal processing cycles comprise rapid thermal anneal cycles.

7. The method of claim 1 in which the steps of patterning regions of the substrate with QWI-initiating material comprises the steps of: depositing photoresist on the substrate;
forming windows in the photoresist coextensive with the region of the substrate to be covered with QWI-initiating material;
depositing the QWI-initiating material onto the substrate; and
lifting the photoresist off the substrate.

8. The method of claim 1 in which the QWI-initiating material comprises an impurity rich material.

9. The method of claim 8 in which the impurity comprises one or more of sulphur, zinc, silicon, fluorine, copper, germanium, tin and selenium.

10. The method of claim 8 in which the impurity-rich material comprises silica doped with one or more of the impurities sulphur, zinc, silicon, fluorine, copper, germanium, tin and selenium.

11. The method of claim 1 in which the QWI-initiating material is sputter deposited.

12. The method of claim 4 in which the QWI-inhibiting material comprises a PECVD-silica layer.

13. The method of claim 1 in which the QWI-initiating material from a given region is removed from the substrate after the first thermal processing cycle to which it is exposed and prior to a subsequent thermal processing cycle.

14. The method of claim 1 in which the QWI-initiating material on a given region is retained on the substrate for subsequent thermal processing cycles.

15. The method of claim 14 in which the QWI-initiating material on a given region is retained on the substrate for all subsequent thermal processing cycles.

16. The method of claim 1 used on an InP/AlInGaAs substrate.

17. The method of claim 1 in which each of the thermal processing cycles is performed for substantially the same length of time.

18. The method of claim 17 in which each of the thermal processing cycles is performed at different temperatures.

19. A method for determining required parameters for each of the thermal processing cycles of the method of claim 1, comprising the steps of:
determining whether the process for generating cumulative bandgap shifts resulting from successive thermal processing cycles is symmetric or asymmetric;
if the process is symmetric, then determining the thermal process conditions required for each one of a plurality of cumulative bandgap shifts BG₁ to BG_{N} by successive use of at least one sample through a thermal process sequence A_{N} to A₁, where A₁ is the thermal process required to obtain BG_{N} from BG_{N-1}; A₂ is the thermal process required to obtain BG_{N-1} from BG_{N-2}; etc.; through to A_{N} being the thermal process required to obtain BG₁ from BG₀; and
if the process is asymmetric, then determining the thermal process conditions required for each one of the plurality of cumulative bandgap shifts BG₁ to BG_{N} by use of a plurality of samples through a partial or complete thermal process sequence in the order A₁ to A_{N} for each one of the bandgap shifts required.

20. The method of claim 19, further comprising the steps of:
(i) establishing thermal processing conditions A_{N} suitable for obtaining the smallest cumulative bandgap shift BG₁ of the Nth region;
(ii) performing a thermal processing cycle on a first sample using A_{N} to obtain bandgap shift BG₁;
(iii) establishing thermal processing conditions A_{N-1} suitable for obtaining the cumulative bandgap shift BG₂ of the N-lth region;
(iv) performing a thermal processing cycle on said first sample, after step (ii), using A_{N-1} to obtain bandgap shift BG₂;
(iv) performing thermal processing cycles A_{N-1} then A_{N} on a second sample to obtain bandgap shift BG₂′;
(v) establishing whether the anneal process is symmetric, i.e., if BG₂=BG₂′, and if so performing steps (vii) to (viii), otherwise performing step (ix);
(vi) establishing thermal processing conditions A_{N-2} suitable for obtaining the cumulative bandgap shift BG₃;
(vii) performing a thermal processing cycle on said first sample, after step (iv), using A_{N-2} to obtain bandgap shift BG₃;
(viii) establishing cumulative thermal processing cycles A₁to A_{N} for each one of the cumulative bandgap shifts BG_{N} to BG₁ on separate samples for each one of the cumulative bandgap shifts required.

21. The method of claim 20 further including the steps of:
re-iterating steps (vii) and (viii) in respect of establishing thermal processing conditions suitable for obtaining further cumulative bandgap shifts and in respect of performing thermal processing cycles on the first and subsequent samples in order to complete step (ix) for each one of the cumulative bandgap shifts required.

22-23. (canceled)
